(19) United States
(12) Patent Application Publication
(10) Pub. No.: US 2024/0186385 A1
(43) Pub. Date: Jun. 6, 2024

(54) Semiconductor Device with Pillar- Shaped Shielded gate structures

(71) Applicant: Nami MOS CO., LTD., New Taipei City (TW)

(72) Inventors: FU-YUAN HSIEH, New Taipei City (TW); LIN XU, Shanghai (CN)

(73) Assignees: Nami MOS CO., LTD., New Taipei City (TW); Shenzhen Puolop Electronics Co., Ltd, Shenzhen (CN)

(21) Appl. No.: 18/173,262

(22) Filed: Feb. 23, 2023

Related U.S. Application Data
(63) Continuation-in-part of application No. 18/073,964, filed on Dec. 2, 2022.

(51) Int. Cl. H01L 29/40; H01L 29/06; H01L 29/10; H01L 29/739; H01L 29/78

(52) U.S. Cl. CPC H01L 29/407; H01L 29/0696; H01L 29/1095; H01L 29/7397; H01L 29/7813

(57) ABSTRACT

A shielded gate trench (SGT) MOSFET with a square or rectangular pillar-shape deep trench and multiple epitaxial layers is disclosed, wherein at least one gate electrode surrounds the deep trench in each wait cell. The at least one gate electrode is planar, or vertically formed in an upper portion of a gate trench in each wait cell. Moreover, a body region is absent in an intersection area of two gate trenches adjacent to corners of the deep trench for breakdown voltage enhancement.

### CROSS REFERENCE TO RELATED APPLICATION

This application is a continuation-In-Part (CIP) of U.S. patent application Ser. No. 18/073,964 of, filed on Oct. 2, 2019 entitled “shielded gate trench MOSFETs with hexagonal deep trench layouts and multiple epitaxial layers”.

### FIELD OF THE INVENTION

This invention relates to a novel and improved cell layout and device configuration of a shielded gate trench (SGT) metal oxide semiconductor field effect transistor (MOSFET, the same hereinafter) to solve wafer warpage issue of the device in medium and high voltage ranges.

### BACKGROUND OF THE INVENTION

Compared with conventional trench MOSFETs. SGT MOSFETs are more attractive due to lower specific drain-source resistance (Rds) and improved overall efficiency in most applications without compromising ruggedness of the device as a result of oxide charge balance (OCB) region formed between the adjacent deep trenches. However, wafer warpage becomes a serious issue for the SGT MOSFET with a stripe shaped deep trench when wafer diameter increases or breakdown voltage increases. Main reasons for the rise of the wafer warpage are given by increasing deep trench depth and increasing field oxide thickness as breakdown voltage and wafer diameter increases. When the wafer warpage exceeds a critical value, an error in vacuum absorption or wafer transportation occurs in some equipment. The wafers cannot be processed anymore.

Please refer to FIG. 1A for an N-channel SGT MOSFET disclosed in a prior art of U.S. Pat. No. US2017/0317207 wherein two gate trenches surround a deep trench in each unit cell of the SGT MOSFT. The deep trench filled with a shielded gate having a square-pillar shape results in much less wafer warpage than the SGT with a stripe shaped deep trench. In which A1′-A2′ cross-sectional view is shown in FIG. 1B. Between every two adjacent deep trenches, there are two gate trenches and three trenched source-body contacts. However, the prior art does not disclose the detailed top view and cross-sectional structure of an intersection area of the two gate trenches near corners of the deep trench shown in FIG. 1A. If a floating P-body is formed in the intersection area, early breakdown issue will occur.

Therefore, there is still a need in the art of the semiconductor power device, particularly for the SGT MOSFET design, to provide a novel cell structure and device configuration that would resolve design limitations and improve device performance.

### SUMMARY OF THE INVENTION

The present invention features a SGT MOSFET comprising a plurality of unit cells with each unit cell in an active area having an OCB region formed in a mesa area between the adjacent deep trenches, comprising: a substrate of a first conductivity type: an epitaxial layer of the first conductivity type grown on the substrate, wherein the epitaxial layer has a lower doping concentration than the substrate: a deep trench formed in each unit cell having a square or rectangular pillar shape filled with a shielded gate electrode surrounded by a first insulating film, starting from a top surface of the epitaxial layer toward the substrate: at least two gate trenches in each unit cell filled with a doped poly-silicon layer as a gate electrode padded by a gate oxide layer surrounding the deep trench: a source region of the first conductivity type surrounding an upper portion of each of the multiple trenched source-body contacts, extending between an upper portion of the at least two gate trenches and the adjacent deep trench, a body region of the second conductivity type formed underneath the source region: the multiple trenched source-body contacts with each filled with a contact metal plug extending into the body region in the mesa area: an intersection area of the at least two gate trenches adjacent to corners of the deep trench wherein the body region is not formed for breakdown voltage enhancement.

According to another aspect of the present invention, a SGT MOSFET comprising a plurality of unit cells with each unit cell in an active area having an OCB region formed in a mesa area between the adjacent deep trenches, comprising: a substrate of a first conductivity type: an epitaxial layer of the first conductivity type grown on the substrate, wherein the epitaxial layer has a lower doping concentration than the substrate: a plurality of deep trenches with a square or rectangular pillar shape filled with a shielded gate electrode surrounded by a first insulating film as a field plate oxide, starting from a top surface of the epitaxial layer toward the substrate; at least one planar gate electrode in each unit cell padded by a gate oxide surrounding the deep trench; a source region of the first conductivity type surrounding an upper portion of each of the multiple trenched source-body contacts, extending between an upper portion of the at least one planar gate electrode and the adjacent deep trench, a body region of the second conductivity type formed underneath the source region: the multiple trenched source-body contacts with each filled with a contact metal plug extending into the body region in the mesa area.

According to another aspect of the present invention, a SGT MOSFET comprising a plurality of unit cells with each unit cell in an active area having an OCB region formed in a mesa area between the adjacent deep trenches, comprising: a substrate of a first conductivity type: an epitaxial layer of the first conductivity type grown on the substrate: each of the unit cells has a deep trench with a square or rectangular pillar-shape filled with a first type shielded gate electrode surrounded by a first insulating film as a field plate oxide, starting from a top surface of the epitaxial layer toward the substrate: at least two gate trenches in each unit cell surrounding the deep trench. A source region of the first conductivity type are encompassed in a body region of a second conductivity type near a top surface of the epitaxial layer, each of the at least two gate trenches is filled with a gate electrode and a second type shielded gate electrode: the second type shielded gate electrode is insulated from the adjacent epitaxial layer by a second insulating film, the gate electrode is insulated from the adjacent epitaxial layer by a gate oxide, the second type shielded gate electrode and the gate electrode are insulated from each other by an (Inter-Poly Oxide) IPO film, the gate oxide surrounds the gate electrode and has a thinner thickness than the second insulating film: the body region, the first type and second type shielded gate electrodes, and the source region are shorted together to a source metal through a trench source-body contact.

According to another aspect of the present invention, in some preferred embodiments, the epitaxial layer is a single epitaxial layer with a uniform doping concentration. In some other preferred embodiments, the epitaxial layer has multiple stepped epitaxial (MSE) layers with different doping concentrations decreasing stepwise in a direction from the substrate to the body regions, wherein each of the MSE layers has a uniform doping concentration as grown.

According to another aspect of the present invention, the epitaxial layer has MSE layers between the body region and a bottom of the shielded gate electrode in the deep trench with different doping concentrations decreasing stepwise in a direction from bottoms of the plurality of shielded gate electrodes in the deep trenches toward the body regions along sidewalls of the plurality of deep trenches, and a buffer epitaxial layer between a bottom of the shielded gate electrode in the deep trench and the substrate, the epitaxial layer in the buffer region has a doping concentration lower than each of the MSE layers.

According to another aspect of the present invention, the epitaxial layer has (MSE layers between the body region and a bottom of the shielded gate electrode in the deep trench with different doping concentrations decreasing stepwise in a direction from bottoms of the plurality of shielded gate electrodes in the deep trenches toward the body regions along sidewalls of the plurality of deep trenches, and a buffer epitaxial layer between a bottom of the shielded gate electrode in the deep trench and the substrate, the epitaxial layer in the buffer region has a doping concentration higher than a top layer of the MSE layers but lower than other layers of the MSE layers.

According to another aspect, the present invention also features a SGT insulted gate bipolar transistor (IGBT) which is formed in an epitaxial layer of a first conductivity type onto a substrate of the second conductivity type.

According to another aspect, in some preferred embodiments, the SGT IGBT further comprising a plurality of heavily doped regions of the first conductivity type in a substrate of the second conductivity type to form a plurality of alternating P+ and N+ regions in the substrate.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1A is a top view of an N-channel SGT MOSFET disclosed in a prior art of U.S. Pat. No. 2017/0317207.

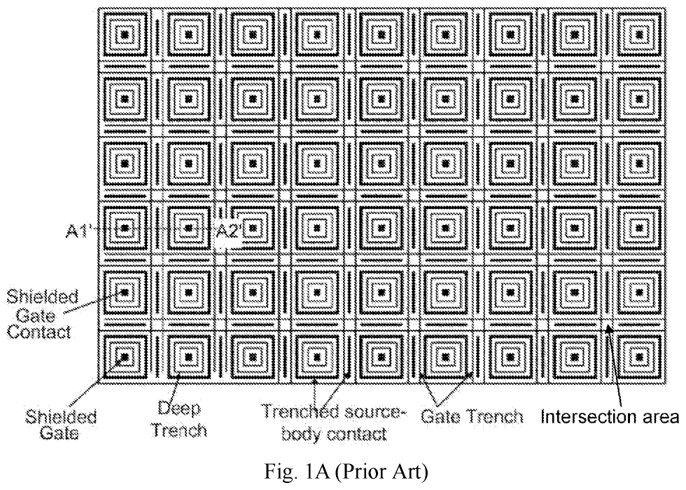

FIG. 1B is an A1′-A2′ cross-sectional view of FIG. 1A disclosed in the prior art of U.S. Pat. No. 2017/0317207.

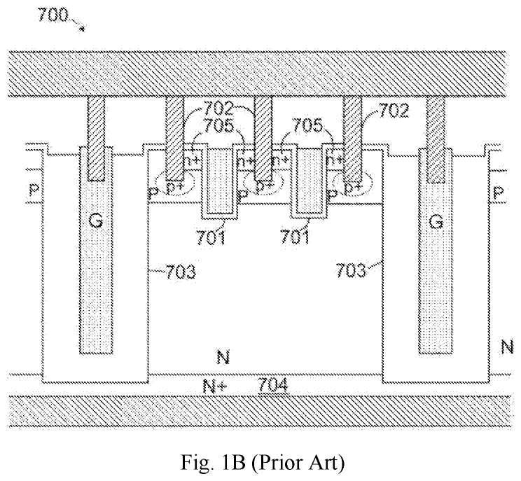

FIG. 2A is a top view of a preferred embodiment of an SGT MOSFET with square closed cells layout according to the present invention.

FIG. 2B is an enlarged top view of FIG. 2A according to the present invention.

FIG. 2C is a preferred cross-sectional view of A2-A2′ in FIG. 2A according to the present invention.

FIG. 2D is a preferred cross-sectional view of B2-B2′ in FIG. 2A according to the present invention.

FIG. 2E is another preferred cross-sectional view of A2-A2′ in FIG. 2A according to the present invention.

FIG. 2F is another preferred cross-sectional view of B2-B2′ in FIG. 2A according to the present invention.

FIG. 3A is a top view of another preferred embodiment of an SGT MOSFET with rectangular closed cells in single orientation according to the present invention.

FIG. 3B is a top view of another preferred embodiment of an SGT MOSFET with rectangular closed cells in multiple orientations according to the present invention.

FIG. 4A is a top view of another preferred embodiment of an SGT MOSFET with each unit cell having a gate poly as a gate electrode according to the present invention.

FIG. 4B is an enlarged top view of FIG. 4A according to the present invention.

FIG. 4C is a preferred cross-sectional view of A1-A1′ in FIG. 4A according to the present invention.

FIG. 4D is a preferred cross-sectional view of B1-B1′ in FIG. 4A according to the present invention.

FIG. 4E is a top view of another preferred embodiment of an SGT MOSFET with rectangular closed cells in single orientation and a gate poly as a gate electrode in each unit cell according to the present invention.

FIG. 5A is another preferred cross-sectional view of A1-A1′ in FIG. 4A with MSE layers according to the present invention.

FIG. 5B is another preferred cross-sectional view of A1-A1′ in FIG. 4A with MSE layers according to the present invention.

FIG. 5C is another preferred cross-sectional view of A1-A1′ in FIG. 4A with MSE layers according to the present invention.

FIG. 6A is another preferred cross-sectional view of A2-A2′ in FIG. 2A with MSE layers according to the present invention.

FIG. 6B is another preferred cross-sectional view of A2-A2′ in FIG. 2A with MSE layers according to the present invention.

FIG. 6C is another preferred cross-sectional view of A2-A2′ in FIG. 2A with MSE layers according to the present invention.

FIG. 7A is another preferred cross-sectional view of A2-A2′ in FIG. 2A with MSE layers according to the present invention.

FIG. 7B is another preferred cross-sectional view of A2-A2′ in FIG. 2A with MSE layers according to the present invention.

FIG. 7C is another preferred cross-sectional view of A2-A2′ in FIG. 2A with MSE layers according to the present invention.

FIG. 8A is another preferred cross-sectional view of A2-A2′ in FIG. 2A with MSE layers according to the present invention.

FIG. 8B is another preferred cross-sectional view of A2-A2′ in FIG. 2A with MSE layers according to the present invention.

FIG. 8C is another preferred cross-sectional view of A2-A2′ in FIG. 2A with MSE layers according to the present invention.

FIG. 9A is another preferred cross-sectional view of A2-A2′ in FIG. 2A with MSE layers according to the present invention.

FIG. 9B is another preferred cross-sectional view of A2-A2′ in FIG. 2A with MSE layers according to the present invention.

FIG. 9C is another preferred cross-sectional view of A2-A2′ in FIG. 2A with MSE layers according to the present invention.

FIG. 10A is another preferred cross-sectional view of A1-A1′ in FIG. 4A with MSE layers according to the present invention.

FIG. 10B is another preferred cross-sectional view of A1-A1′ in FIG. 4A with MSE layers according to the present invention.

FIG. 10C is another preferred cross-sectional view of A1-A1′ in FIG. 4A with MSE layers according to the present invention.

FIG. 11A is another preferred cross-sectional view of A1-A1′ in FIG. 4A with MSE layers according to the present invention.

FIG. 11B is another preferred cross-sectional view of A1-A1′ in FIG. 4A with MSE layers according to the present invention.

FIG. 11C is another preferred cross-sectional view of A1-A1′ in FIG. 4A with MSE layers according to the present invention.

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be make without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

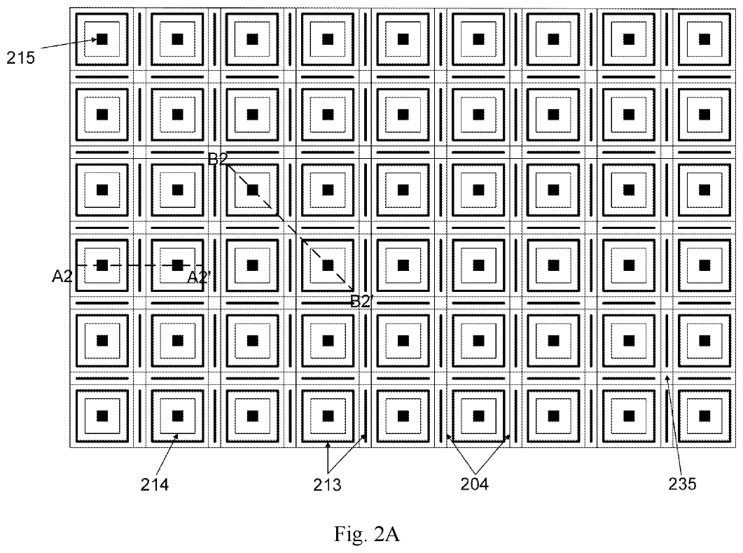

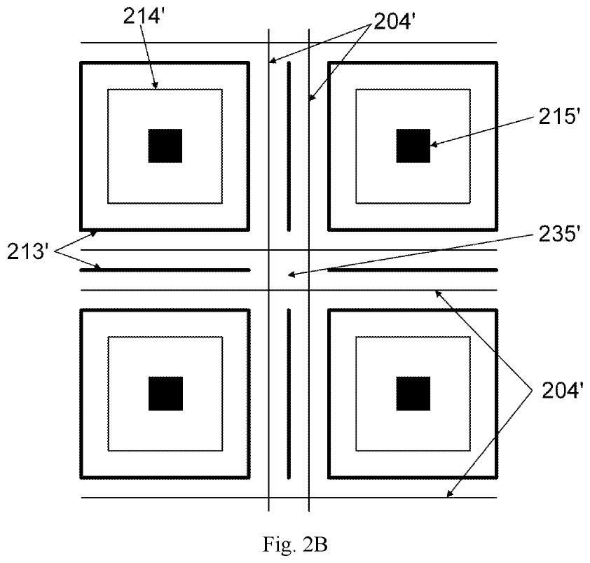

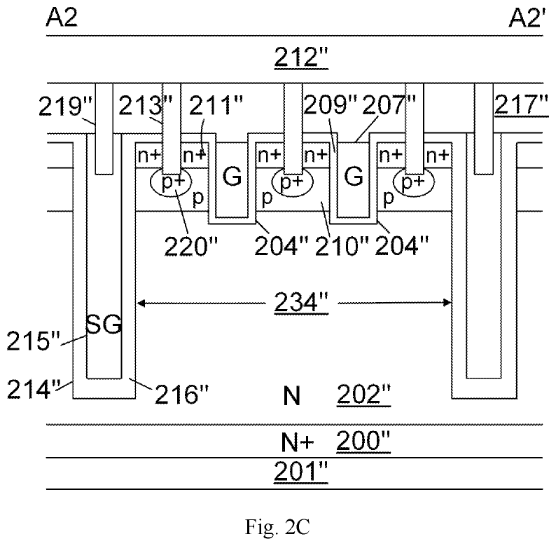

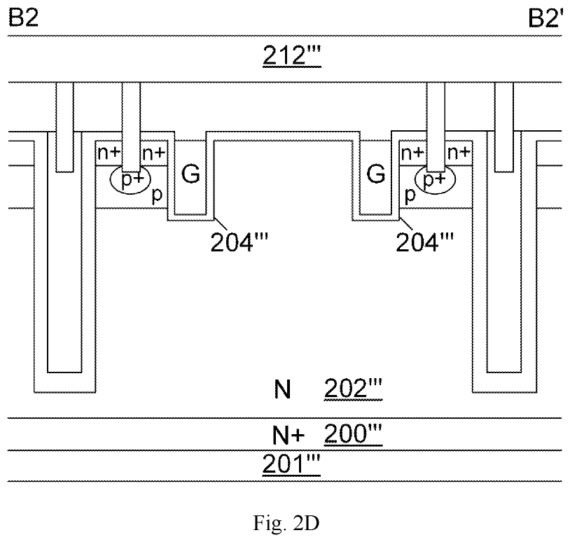

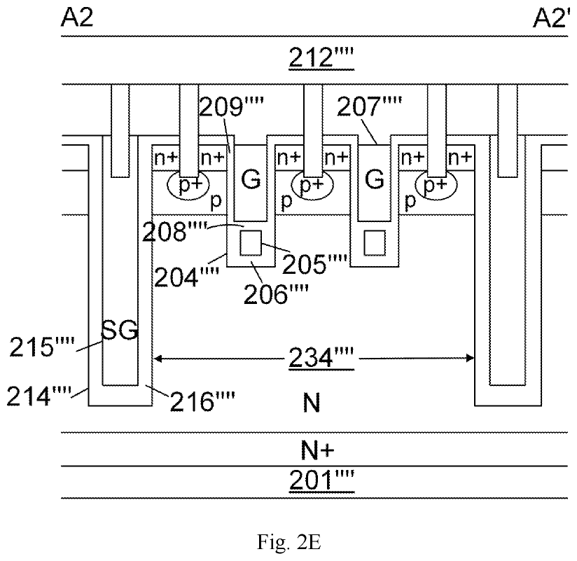

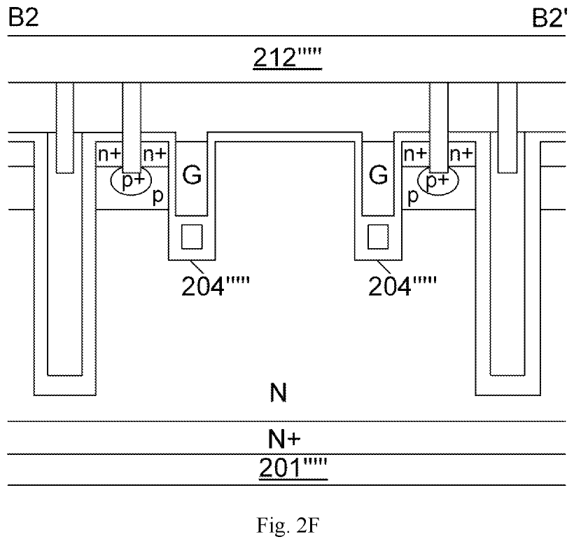

Please refer to FIG. 2A for a top view of a preferred embodiment for a SGT semiconductor power device comprising a plurality of square-shaped unit cells with each unit cell in an active area having an OCB region formed in a mesa area between the adjacent deep trenches 214. Each of the unit cells has a deep trench 214 with a square shape filled with a shielded gate contact 215 and surrounded by at least two gate trenches 204. A source contact 213 is formed between the at least two gate trenches 204, and between gate trench 204 and its adjacent deep trench 214. Moreover, source and body regions are not formed in an intersection area 235 of the at least two gate trenches 204 adjacent to corners of the deep trench 214 for breakdown voltage enhancement.

Please refer to FIG. 2B for an enlarged top view of FIG. 2A with square closed cells layout. Each of the unit cells has a deep trench 214′ with a square shape filled with a shielded gate contact 215′ and surrounded by at least two gate trenches 204′. A source contact 213′ is formed between the at least two gate trenches 204′, and between gate trench 204′ and its adjacent deep trench 214′. Moreover, body regions are not formed in an intersection area 235′ of the at least two gate trenches 204′ adjacent to corners of the deep trench 214′ for breakdown voltage enhancement.

Please refer to FIG. 2C for a cross-sectional view showing a preferred A2-A2′ cross section of FIG. 2A with a single epitaxial layer according to the present invention. The preferred embodiment comprises an N-channel SGT MOSFET formed in an N type epitaxial layer 202″ onto an N+ substrate 200″ coated with a back metal 201″ of Ti/Ni/Ag on rear side as a drain metal. Inside the N type epitaxial layer 202″, a plurality of deep trenches 214″ are formed vertically downward from a top surface of the N type epitaxial layer 202″ and not reaching the common interface between the N type epitaxial layer 202″ and the N+ substrate 200″. Each deep trench 214″ is filled with a shielded gate electrode 215″ (SG, as illustrated) surrounded by a first insulating film 216″ as a field plate oxide. At least two gate trenches 204″ are formed surrounding the deep trench 214″ as a closed shape in an active area, wherein there are multiple closed shape cells in the active area. In a mesa area 234″ between the adjacent deep trenches 214″, the at least two gate trenches 204″ are formed extending from a top surface of the N type epitaxial layer 202″ and vertically downward into the N type epitaxial layer 202″, wherein the gate trench 204″ has a shallower trench depth than the deep trench 214″. Inside each of the gate trenches 204″, a doped poly-silicon layer is formed as a single gate electrode (G, as illustrated) 207″ padded by a gate oxide layer 209″. Between the at least two gate trenches 204″, and between gate trench 204″ and its adjacent deep trench 214″. P body regions 210″ with n+ source regions 211″ thereon are extending near top surface of the N type epitaxial layer 202″. The P body regions 210″, the n+ source regions 211″, and the shielded gate electrode 215′ are further shorted together to a source metal 212″ through a plurality of trenched contacts 213″ or 219″ filled with contact metal plugs and metal barriers implemented by penetrating through a contact insulating layer 217″ and into p+ heavily doped regions 220″ around bottoms underneath the n+ source regions 211″ or the shielded gate electrode 215″. According to the invention, an OCB region is therefore formed in a mesa area 234″ between the adjacent deep trenches 214″.

Please refer to FIG. 2D for a cross-sectional view showing a preferred B2-B2′ cross section of FIG. 2A with a single epitaxial layer according to the present invention. The N-channel trenched semiconductor power device has a similar structure to FIG. 2C, except that, in FIG. 2D, the trenched contacts, n+ source and P body regions are absent between the at least two gate trenches 204″″ for breakdown voltage enhancement.

Please refer to FIG. 2E for a cross-sectional view showing another preferred A2-A2′ cross section of FIG. 2A with a single epitaxial layer according to the present invention. The N-channel trenched semiconductor power device has a similar structure to FIG. 2C, except for the different gate trench structure in the mesa area 234″″. In FIG. 2E, each deep trench 214″″ is filled with a first type shielded gate electrode 215″″ surrounded by a first insulating film 216″″ as a field plate oxide. Inside each of the gate trenches 204″″, a second type shielded gate electrode 205″″ is disposed in the lower portion and a gate electrode (G, as illustrated) 207″″ is disposed in the upper portion above the shielded gate electrode 205″″. The second type shielded gate electrode 205″″ is insulated from the adjacent epitaxial layer by a second insulating film 206″, and the gate electrode 207″ is insulated from the adjacent epitaxial layer by a gate oxide 209″″, wherein the gate oxide 209″″ has a thinner thickness than the second insulating film 206″″ which has a uniform thickness along trench sidewalls, meanwhile, the second type shielded gate electrode 205″″ and the gate electrode 207″ are insulated from each other by an IPO film 208″.

Please refer to FIG. 2F for a cross-sectional view showing another preferred B2-B2′ cross section of FIG. 2A with a single epitaxial layer according to the present invention. The N-channel trenched semiconductor power device has a similar structure to FIG. 2E, except that, in this invention, the trenched contacts, n+ source and P body regions are absent between the at least two gate trenches 204″″ for breakdown voltage enhancement.

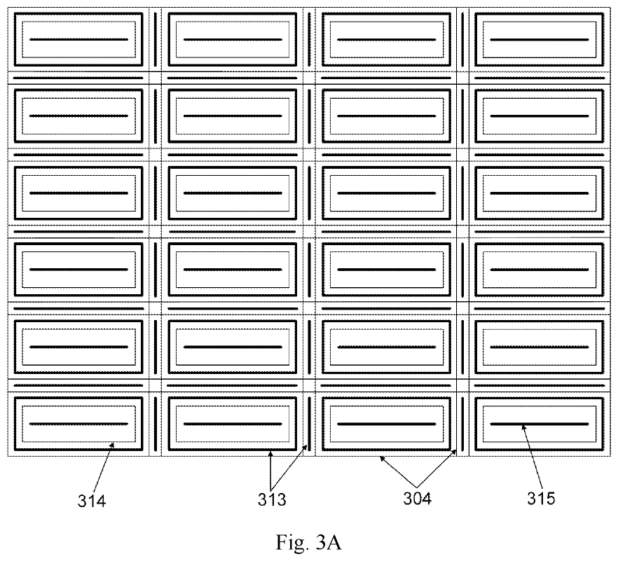

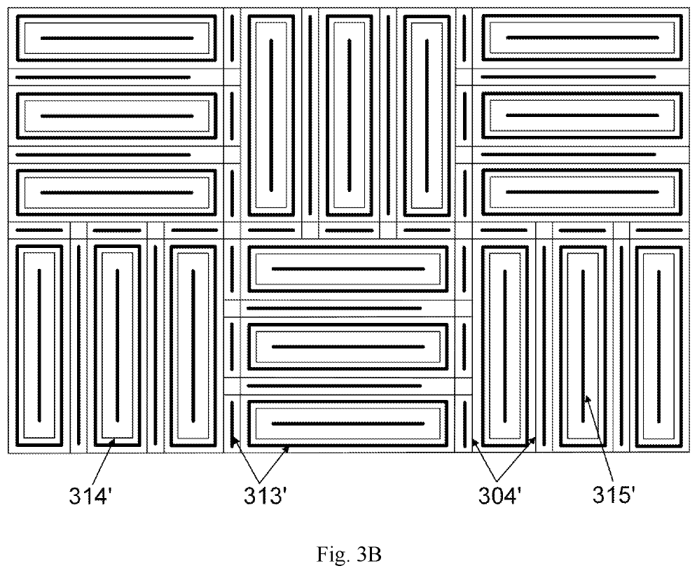

Please refer to FIG. 3A for a top view of another preferred embodiment for a SGT semiconductor power device comprising a plurality of rectangular closed unit cells in single orientation with each unit cell in an active area having an OCB region formed in a mesa area between the adjacent deep trenches 314. Each of the unit cells has a deep trench 314 with a rectangular shape filled with a shielded gate contact 315 and surrounded by at least two gate trenches 304. A source contact 313 is formed between the gate trenches 304, and between gate trench 304 and its adjacent deep trench 314.

Please refer to FIG. 3B for a top view of another preferred embodiment for a SGT semiconductor power device comprising a plurality of rectangular closed unit cells in multiple orientations with each unit cell in an active area having an OCB region formed in a mesa area between the adjacent deep trenches 314′. Each of the unit cells has a deep trench 314′ with a rectangular shape filled with a shielded gate contact 315′ and surrounded by at least two gate trenches 304′. A source contact 313′ is formed between the gate trenches 304′, and between gate trench 304′ and its adjacent deep trench 314′.

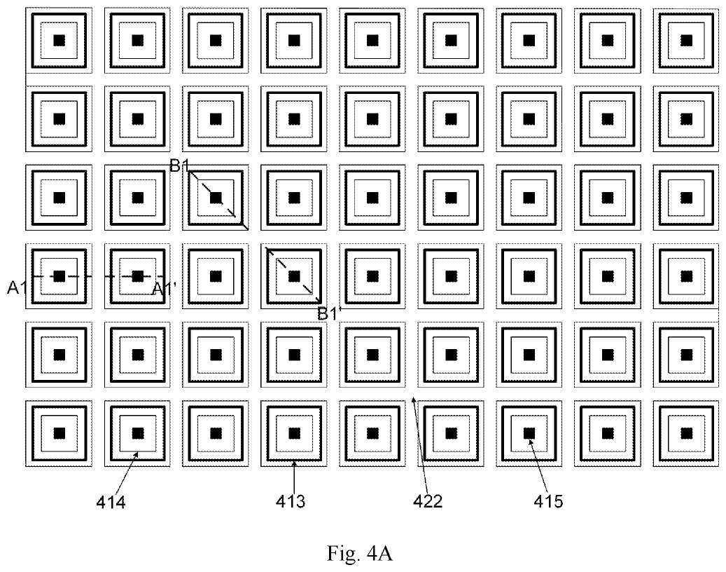

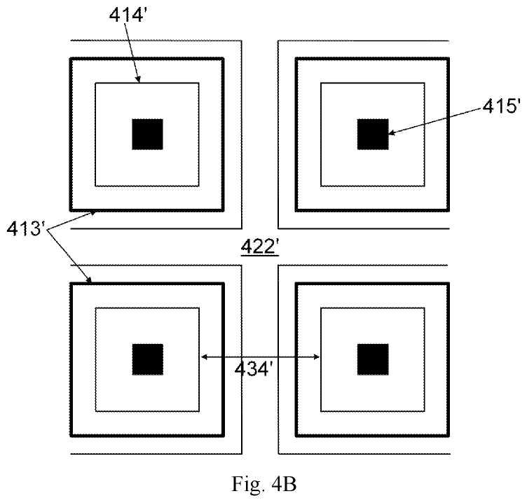

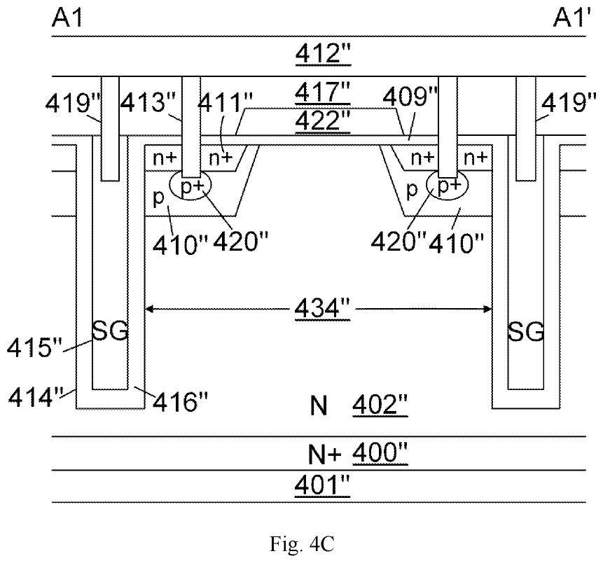

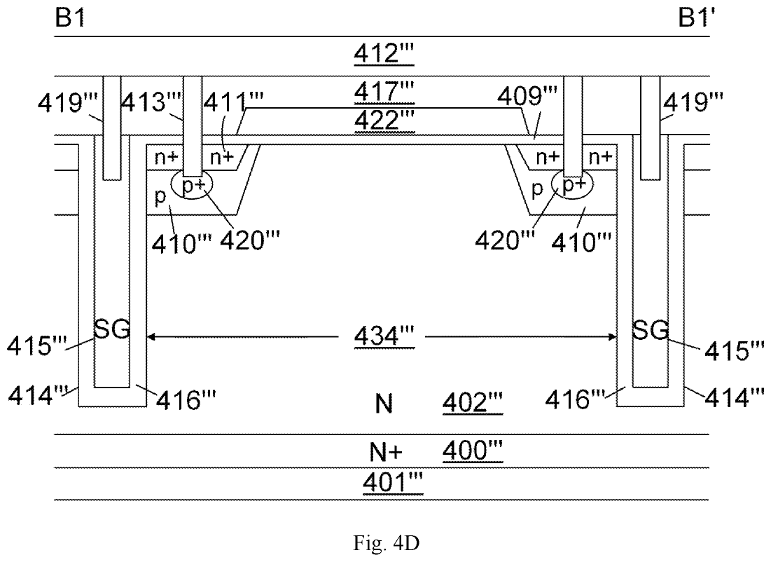

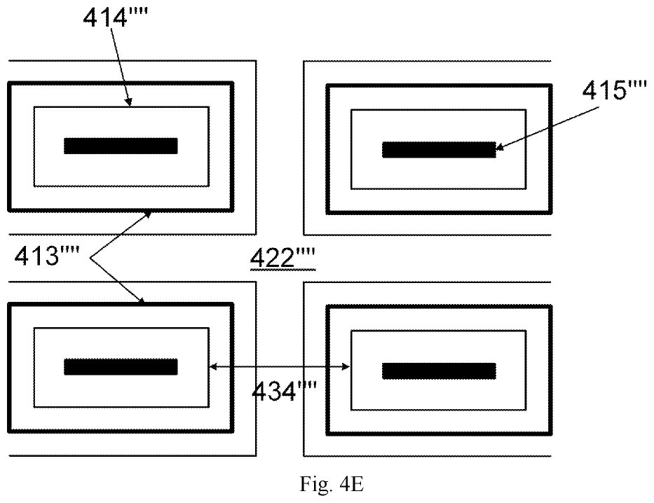

Please refer to FIG. 4A for a top view of another preferred embodiment for a SGT semiconductor power device comprising a plurality of square-shaped unit cells with each unit cell in an active area having an OCB region formed in a mesa area between the adjacent deep trenches 414. Each of the unit cells has a deep trench 414 with a square shape filled with a shielded gate contact 415 and surrounded by a gate poly silicon layer 422 as a gate electrode. A source contact 413 is formed between the gate poly silicon layer 422 and the deep trench 414.

Please refer to FIG. 4B for an enlarged top view of FIG. 4A with square closed cells layout, wherein the mesa area 434′ is marked. Each of the unit cells has a deep trench 414′ with a square shape filled with a shielded gate contact 415′ and surrounded by a planar gate poly silicon layer 422′ as a planar gate electrode. A source contact 413′ is formed between the planar gate poly silicon layer 422′ and the deep trench 414′.

Please refer to FIG. 4C for a cross-sectional view showing a preferred A1-A1′ cross section of FIG. 4A with a single epitaxial layer according to the present invention. The N-channel trenched semiconductor power device has a similar structure to FIG. 2C, except for the different gate electrode structure in the mesa area 434″. In FIG. 4C, a planar gate poly silicon layer 422″ as a gate electrode padded by a gate oxide 409″ is formed surrounding a deep trench 414″ with a pillar shape.

Please refer to FIG. 4D for a cross-sectional view showing a preferred B1-B1′ cross section of FIG. 4A with a single epitaxial layer according to the present invention. The N-channel trenched semiconductor power device has a similar structure to FIG. 2D, except for the different gate electrode structure in the mesa area 434″. In FIG. 4D, a planar gate poly silicon layer 422′″ as a gate electrode padded by a gate oxide 409″″ is formed surrounding a deep trench 414″″ with a pillar shape.

Please refer to FIG. 4E for a top view of another preferred embodiment for a SGT semiconductor power device comprising a plurality of rectangular-shaped unit cells in single orientation with each unit cell having an OCB region formed in a mesa area 434″″ between the adjacent deep trenches 414″″. Each of the unit cells has a deep trench 414″″ with a rectangular shape filled with a shielded gate contact 415″″ and surrounded by a planar gate poly silicon layer 422″″ as a planar gate electrode. A source contact 413″″ is formed between the planar gate poly silicon layer 422″ and the deep trench 414″″.

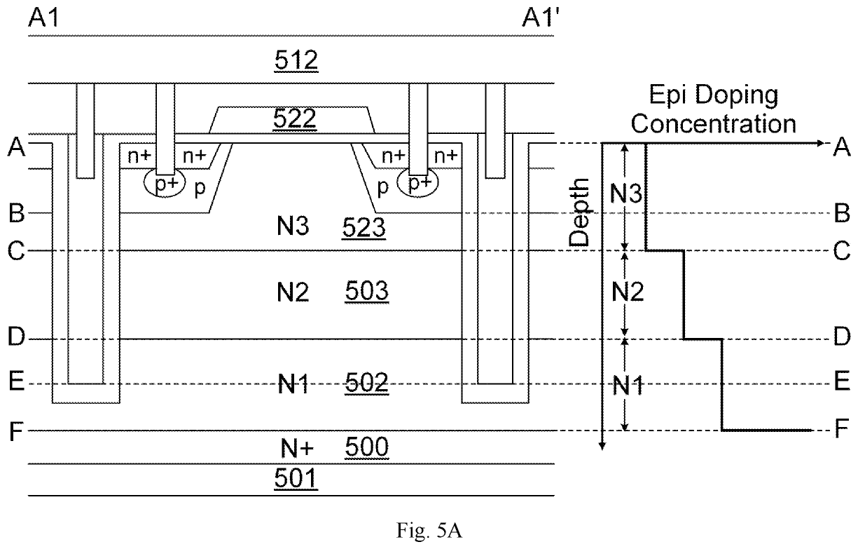

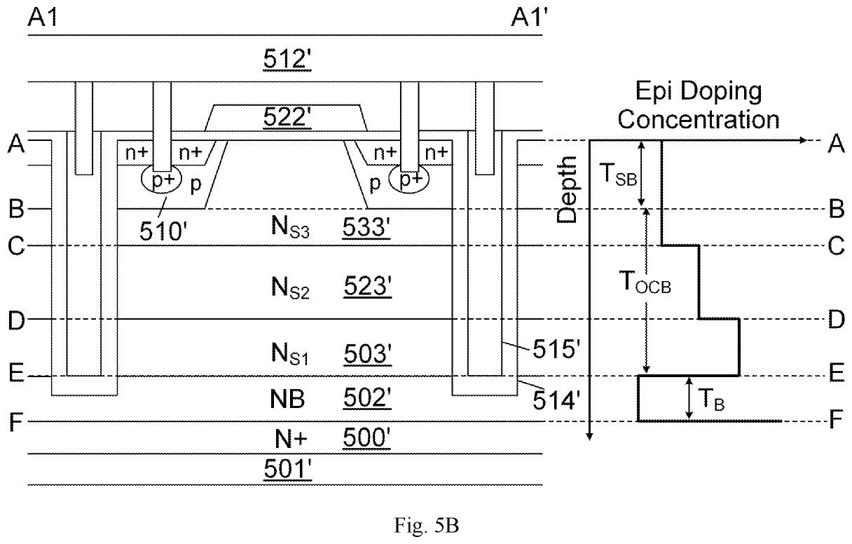

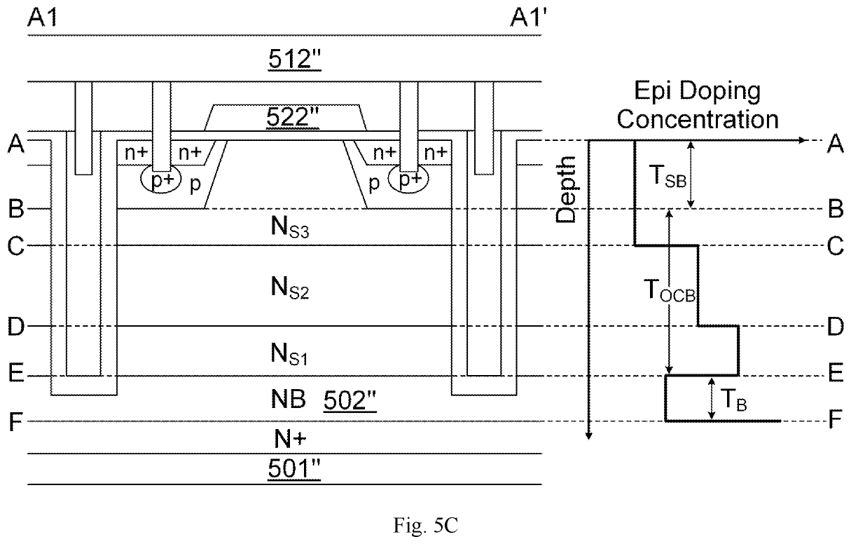

Please refer to FIG. 5A for a cross-sectional view showing another preferred A1-A1′ cross section of FIG. 4A with new and improved device structure having three stepped epitaxial layers wherein the doping concentration variations are depicted along the vertical direction according to the present invention. The N-channel trenched semiconductor power device has a similar structure to FIG. 4C, except that, in FIG. 5A, the N type epitaxial layer comprises three stepped epitaxial layers of different doping concentration including a bottom 1^{st} epitaxial layer (N1, as illustrated between D-D and F-F lines) 502 a with doping concentration D1, a middle 2^{nd} epitaxial layer (N2, as illustrated between C-C and D-D lines) 503 with a doping concentration D2 and a top 3^{rd} epitaxial layer (N3, as illustrated between A-A and C-C lines) 523 with a doping concentration D3, wherein D3<D2<D1, to further reduce the specific on-resistance. The D2 can be an average of D1 and D3.

Please refer to FIG. 5B for a cross-sectional view showing another preferred A1-A1′ cross section of FIG. 4A with new and improved device structure having multiple stepped epitaxial layers wherein the doping concentration variations as grown are depicted along the vertical direction. The N-channel trenched semiconductor power device has a similar structure to FIG. 5A, except for the different epitaxial layer structure. In FIG. 5B, an OCB region T_{OCB} is formed in a mesa area between the two adjacent deep trenches 514′ below the body regions 510′ and above a bottom of the shielded gate electrode 515′ in the deep trench 514′ (between B-B and E-E lines), a buffer region T_{B} is formed between the N+ substrate 500′ and a bottom of the shielded gate electrode 515′ (between E-E and F-F lines), the epitaxial layer in the OCB region has at least three stepped epitaxial layers with different doping concentrations including a bottom 1^{st} epitaxial layer (N_{S1}, as illustrated between D-D and E-E lines) 503′ above the buffer epitaxial layer (N_{B}, as illustrated between E-E and F-F lines) 502′ with a doping concentration D1, a middle 2^{nd} epitaxial layer (N_{S2}, as illustrated between C-C and D-D lines) 523′ above the 1^{st} epitaxial layer 503′ with a doping concentration D2 and a top 3^{rd} epitaxial layer (N_{S3}, as illustrated between B-B and C-C lines) 533′ above the 2^{nd} epitaxial layer 523′ with a doping concentration D3, wherein D3<D2<D1. The D2 can be an average of D1 and D3. Moreover, the epitaxial layer in the source regions and body regions T_{SB} has a doping concentration same as the top 3^{rd} epitaxial layer 533′ of the MSE layers in the OCB region T_{OCB}, and the buffer epitaxial layer 502′ has a doping concentration D_{B} lower than each of the MSE layers in the OCB region T_{OCB}.

Please refer to FIG. 5C for a cross-sectional view showing another preferred A1-A1′ cross section of FIG. 4A with new and improved device structure having multiple stepped epitaxial layers wherein the doping concentration variations as grown are depicted along the vertical direction. The N-channel trenched semiconductor power device has a similar structure to FIG. 5B, except that, in FIG. 5C, the buffer epitaxial layer (N_{B}, as illustrated between E-E and F-F lines) 502″ has a doping concentration D_{B} higher than a top layer of the MSE layers in the OCB region T_{OCB} but lower than other layers of the MSE layers in the OCB region T_{OCB}.

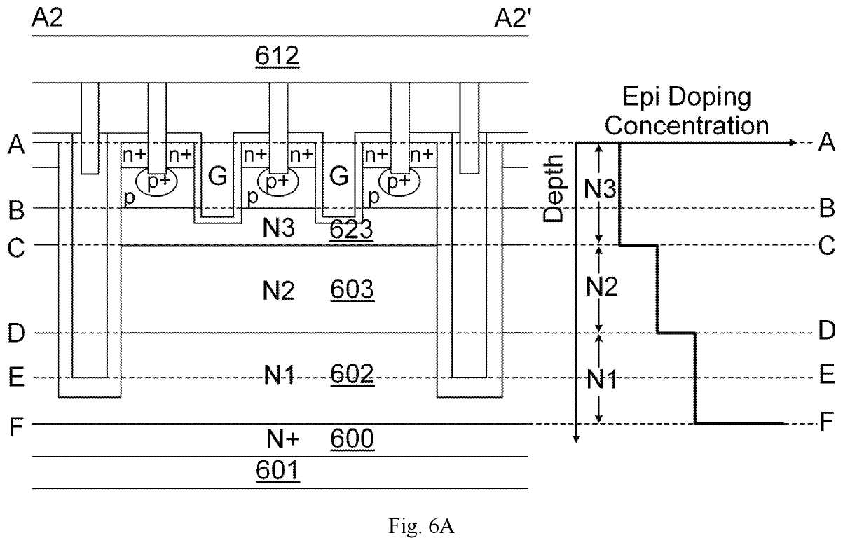

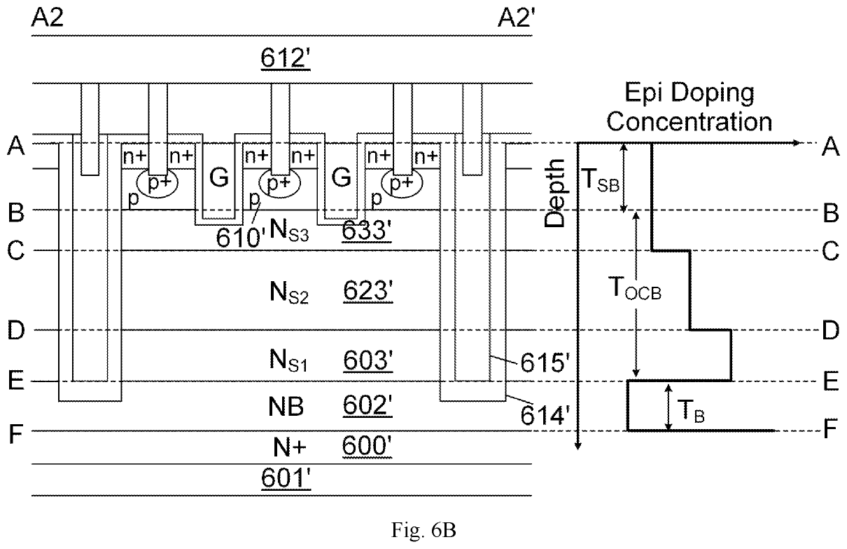

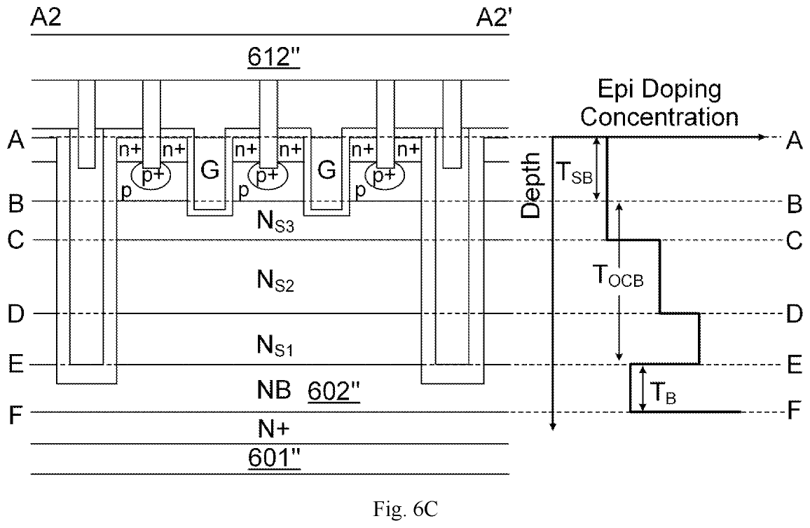

Please refer to FIG. 6A for a cross-sectional view showing another preferred A2-A2′ cross section of FIG. 2A with new and improved device structure having three stepped epitaxial layers wherein the doping concentration variations are depicted along the vertical direction according to the present invention. The N-channel trenched semiconductor power device has a similar structure to FIG. 2C, except that, in FIG. 6A, the N type epitaxial layer comprises three stepped epitaxial layers of different doping concentration including a bottom 1^{st} epitaxial layer (N1, as illustrated between D-D and F-F lines) 602 a with doping concentration D1, a middle 2^{nd} epitaxial layer (N2, as illustrated between C-C and D-D lines) 603 with a doping concentration D2 and a top 3^{rd} epitaxial layer (N3, as illustrated between A-A and C-C lines) 623 with a doping concentration D3, wherein D3<D2<D1, to further reduce the specific on-resistance. The D2 can be an average of D1 and D3.

Please refer to FIG. 6B for a cross-sectional view showing another preferred A2-A2′ cross section of FIG. 2A with new and improved device structure having multiple stepped epitaxial layers wherein the doping concentration variations as grown are depicted along the vertical direction. The N-channel trenched semiconductor power device has a similar structure to FIG. 6A, except for the different epitaxial layer structure. In FIG. 6B, an OCB region T_{OCB} is formed in a mesa area between the two adjacent deep trenches 614′ below the body regions 610′ and above a bottom of the shielded gate electrode 615′ in the deep trench 614′ (between B-B and E-E lines), a buffer region T_{B} is formed between the N+ substrate 600′ and a bottom of the shielded gate electrode 615′ (between E-E and F-F lines), the epitaxial layer in the OCB region has at least three stepped epitaxial layers with different doping concentrations including a bottom 1^{st} epitaxial layer (N_{S1}, as illustrated between D-D and E-E lines) 603′ above the buffer epitaxial layer (N_{B}, as illustrated between E-E and F-F lines) 602′ with a doping concentration D1, a middle 2^{nd} epitaxial layer (N_{S2}, as illustrated between C-C and D-D lines) 623′ above the 1^{st} epitaxial layer 603′ with a doping concentration D2 and a top 3^{rd} epitaxial layer (N_{S3}, as illustrated between B-B and C-C lines) 633′ above the 2^{nd} epitaxial layer 623′ with a doping concentration D3, wherein D3<D2<D1. The D2 can be an average of D1 and D3. Moreover, the epitaxial layer in the source regions and body regions T_{SB} has a doping concentration same as the top 3^{rd} epitaxial layer 633′ of the MSE layers in the OCB region T_{OCB}, and the buffer epitaxial layer 602′ has a doping concentration D_{B} lower than each of the MSE layers in the OCB region T_{OCB}.

Please refer to FIG. 6C for a cross-sectional view showing another preferred A2-A2′ cross section of FIG. 2A with new and improved device structure having multiple stepped epitaxial layers wherein the doping concentration variations as grown are depicted along the vertical direction. The N-channel trenched semiconductor power device has a similar structure to FIG. 6B, except that, in FIG. 6C, the buffer epitaxial layer (N_{B}, as illustrated between E-E and F-F lines) 602″ has a doping concentration D_{B} higher than a top layer of the MSE layers in the OCB region T_{OCB} but lower than other layers of the MSE layers in the OCB region T_{OCB}.

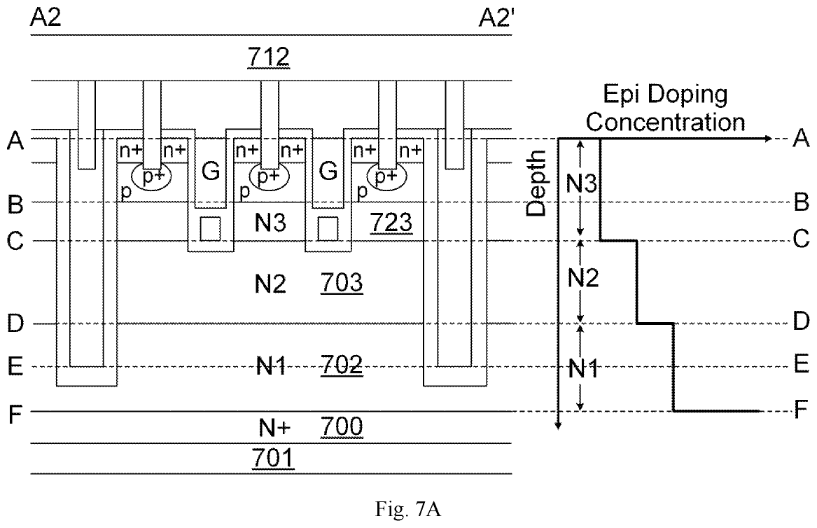

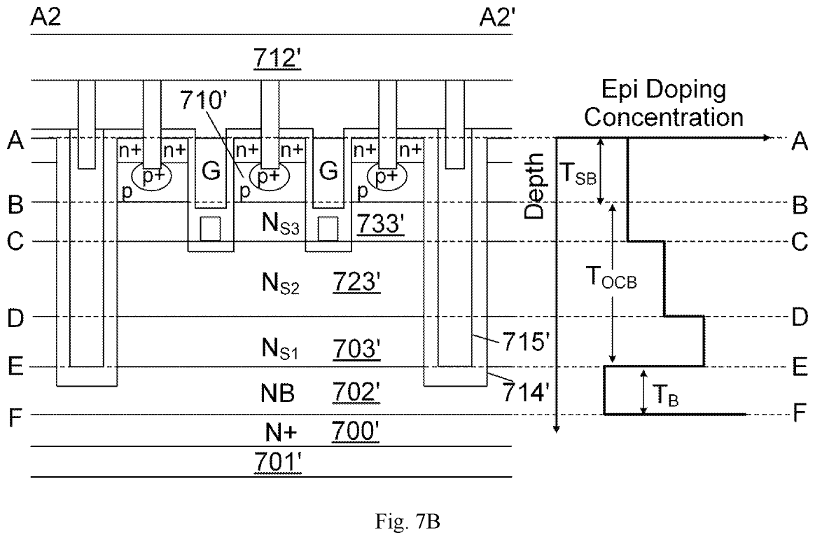

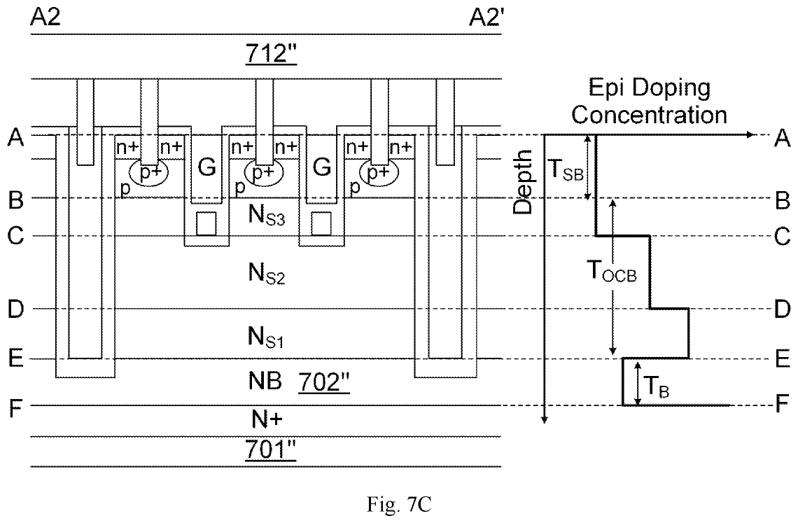

Please refer to FIG. 7A for a cross-sectional view showing another preferred A2-A2′ cross section of FIG. 2A with new and improved device structure having three stepped epitaxial layers wherein the doping concentration variations are depicted along the vertical direction according to the present invention. The N-channel trenched semiconductor power device has a similar structure to FIG. 2E, except that, in FIG. 7A, the N type epitaxial layer comprises three stepped epitaxial layers of different doping concentration including a bottom 1^{st} epitaxial layer (N1, as illustrated between D-D and F-F lines) 702 with a doping concentration D1, a middle 2^{nd} epitaxial layer (N2, as illustrated between C-C and D-D lines) 703 with a doping concentration D2 and a top 3^{rd} epitaxial layer (N3, as illustrated between A-A and C-C lines) 723 with a doping concentration D3, wherein D3<D2<D1, to further reduce the specific on-resistance. The D2 can be an average of D1 and D3.

Please refer to FIG. 7B for a cross-sectional view showing another preferred A2-A2′ cross section of FIG. 2A with new and improved device structure having multiple stepped epitaxial layers wherein the doping concentration variations as grown are depicted along the vertical direction. The N-channel trenched semiconductor power device has a similar structure to FIG. 7A, except for the different epitaxial layer structure. In FIG. 7B, an OCB region T_{OCB} is formed in a mesa area between the two adjacent deep trenches 714′ below the body regions 710′ and above a bottom of the shielded gate electrode 715′ in the deep trench 714′ (between B-B and E-E lines), a buffer region T_{B} is formed between the N+ substrate 700′ and a bottom of the shielded gate electrode 715′ (between E-E and F-F lines), the epitaxial layer in the OCB region has at least three stepped epitaxial layers with different doping concentrations including a bottom 1^{st} epitaxial layer (N_{S1}, as illustrated between D-D and E-E lines) 703′ above the buffer epitaxial layer (N_{B}, as illustrated between E-E and F-F lines) 702′ with a doping concentration D1, a middle 2^{nd} epitaxial layer (N_{S2}, as illustrated between C-C and D-D lines) 723′ above the 1^{st} epitaxial layer 703′ with a doping concentration D2 and a top 3^{rd} epitaxial layer (N_{S3}, as illustrated between B-B and C-C lines) 733′ above the 2^{nd} epitaxial layer 723′ with a doping concentration D3, wherein D3<D2<D1. The D2 can be an average of D1 and D3. Moreover, the epitaxial layer in the source regions and body regions T_{SB} has a doping concentration same as the top 3^{rd} epitaxial layer 733′ of the MSE layers in the OCB region T_{OCB}, and the buffer epitaxial layer 702′ has a doping concentration D_{B} lower than each of the MSE layers in the OCB region T_{OCB}.

Please refer to FIG. 7C for a cross-sectional view showing another preferred A2-A2′ cross section of FIG. 2A with new and improved device structure having multiple stepped epitaxial layers wherein the doping concentration variations as grown are depicted along the vertical direction. The N-channel trenched semiconductor power device has a similar structure to FIG. 7B, except that, in FIG. 7C, the buffer epitaxial layer (N_{B}, as illustrated between E-E and F-F lines) 702″ has a doping concentration D_{B} higher than a top layer of the MSE layers in the OCB region T_{OCB} but lower than other layers of the MSE layers in the OCB region T_{OCB}.

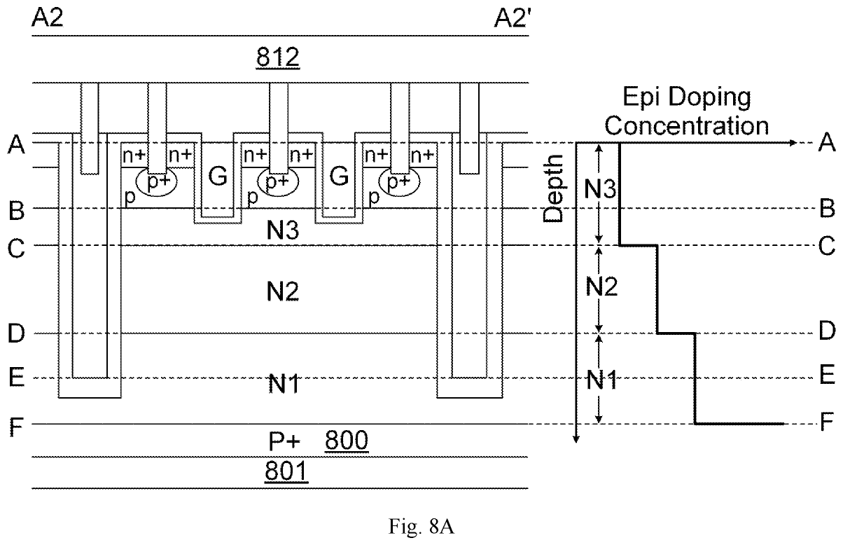

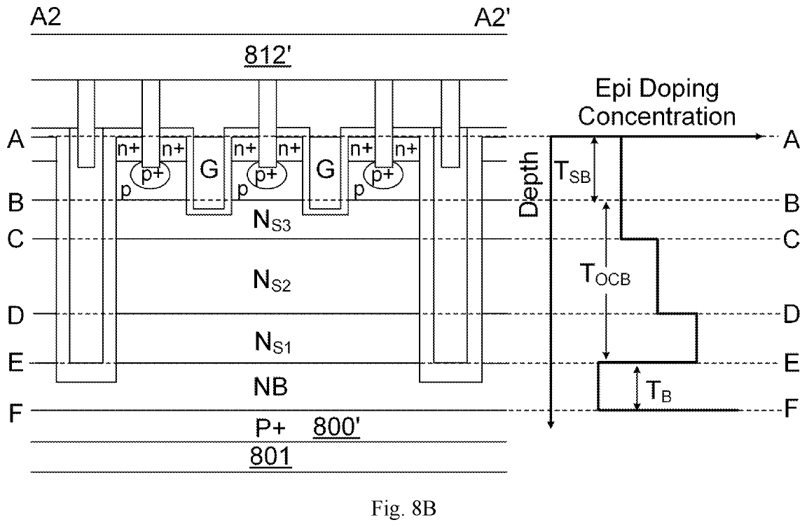

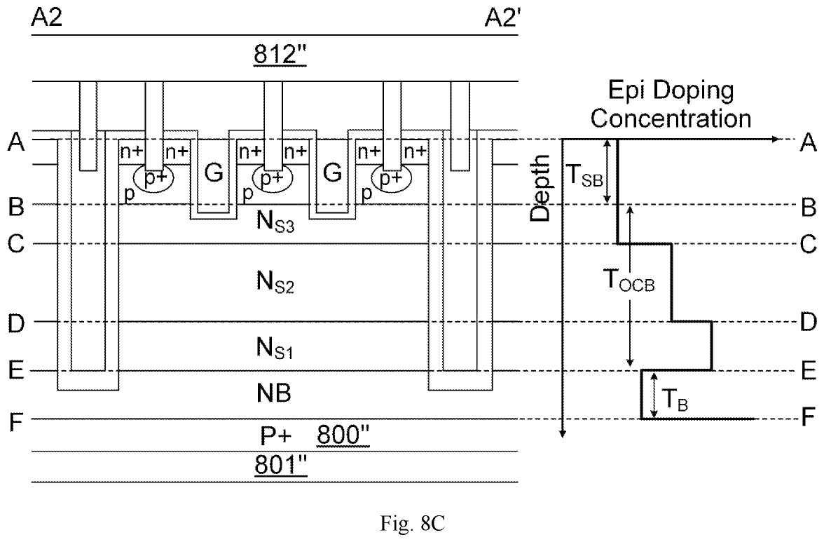

Please refer to FIG. 8A for a cross-sectional view showing another preferred A2-A2′ cross section of FIG. 2A with new and improved device structure having three stepped epitaxial layers wherein the doping concentration variations are depicted along the vertical direction according to the present invention. The N-channel trenched semiconductor power device representing an IGBT device has a similar structure to FIG. 6A, except for the different substrate. In this invention, the IGBT is formed onto a P+ substrate 800.

Please refer to FIG. 8B for a cross-sectional view showing another preferred A2-A2′ cross section of FIG. 2A with new and improved device structure having multiple stepped epitaxial layers wherein the doping concentration variations are depicted along the vertical direction according to the present invention. The N-channel trenched semiconductor power device representing an IGBT device has a similar structure to FIG. 6B, except for the different substrate. In this invention, the IGBT is formed onto a P+ substrate 800′.

Please refer to FIG. 8C for a cross-sectional view showing another preferred A2-A2′ cross section of FIG. 2A with new and improved device structure having multiple stepped epitaxial layers wherein the doping concentration variations are depicted along the vertical direction according to the present invention. The N-channel trenched semiconductor power device representing an IGBT device has a similar structure to FIG. 6C, except for the different substrate. In this invention, the IGBT is formed onto a P+ substrate 800″.

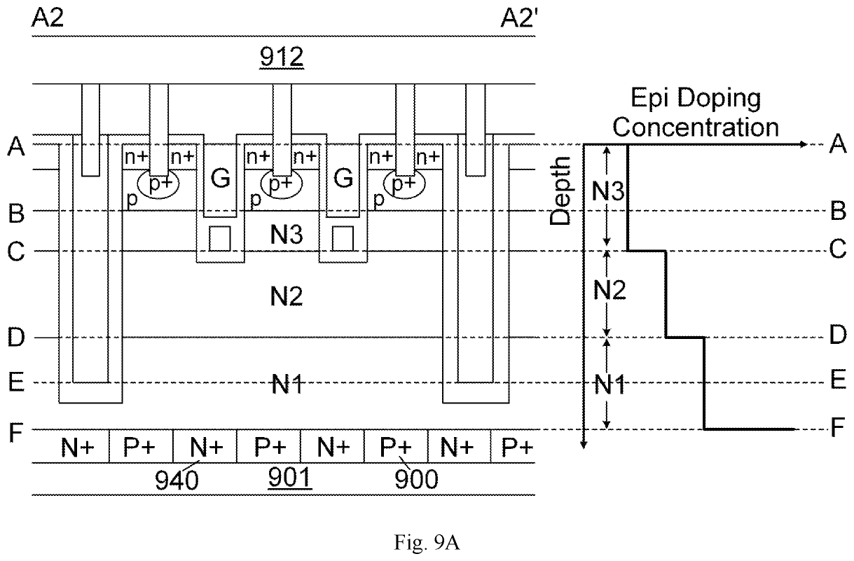

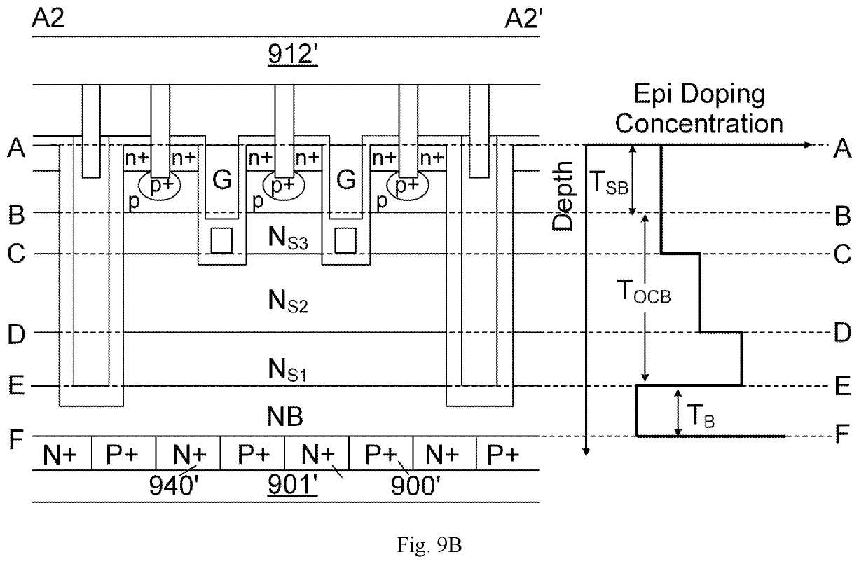

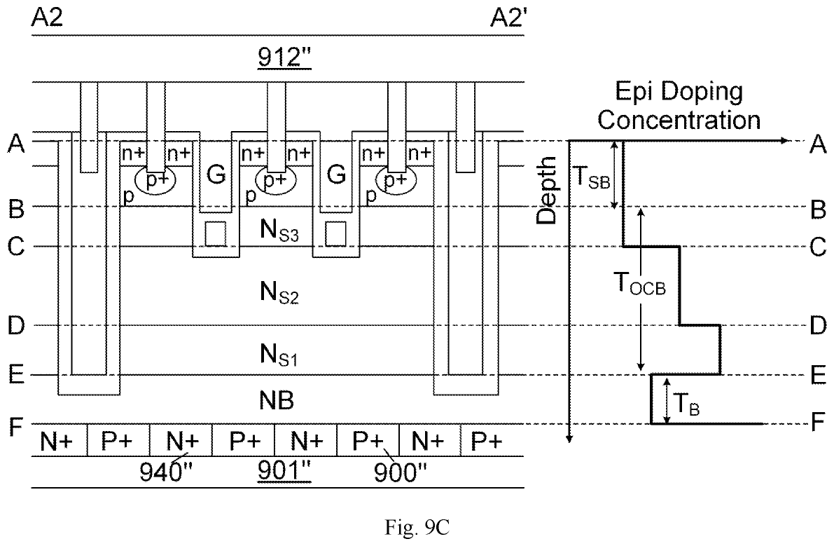

Please refer to FIG. 9A for a cross-sectional view showing another preferred e A2-A2′ cross section of FIG. 2A with new and improved device structure having three stepped epitaxial layers wherein the doping concentration variations are depicted along the vertical direction according to the present invention. The N-channel trenched semiconductor power device representing an IGBT device has a similar structure to FIG. 7A, except that, in FIG. 9A, the IGBT is formed onto a P+ substrate 900, and further comprises a plurality of heavily doped N+ regions 940 formed in the P+ substrate 900 to form a plurality of alternating P+ and N+ regions in the substrate.

Please refer to FIG. 9B for a cross-sectional view showing another preferred e A2-A2′ cross section of FIG. 2A with new and improved device structure having multiple stepped epitaxial layers wherein the doping concentration variations are depicted along the vertical direction according to the present invention. The N-channel trenched semiconductor power device representing an IGBT device has a similar structure to FIG. 7B, except that, in FIG. 9B, the IGBT is formed onto a P+ substrate 900′, and further comprises a plurality of heavily doped N+ regions 940′ formed in the P+ substrate 900′ to form a plurality of alternating P+ and N+ regions in the substrate.

Please refer to FIG. 9C for a cross-sectional view showing another preferred e A2-A2′ cross section of FIG. 2A with new and improved device structure having multiple stepped epitaxial layers wherein the doping concentration variations are depicted along the vertical direction according to the present invention. The N-channel trenched semiconductor power device representing an IGBT device has a similar structure to FIG. 7C, except that, in FIG. 9C, the IGBT is formed onto a P+ substrate 900″, and further comprises a plurality of heavily doped N+ regions 940″ formed in the P+ substrate 900″ to form a plurality of alternating P+ and N+ regions in the substrate.

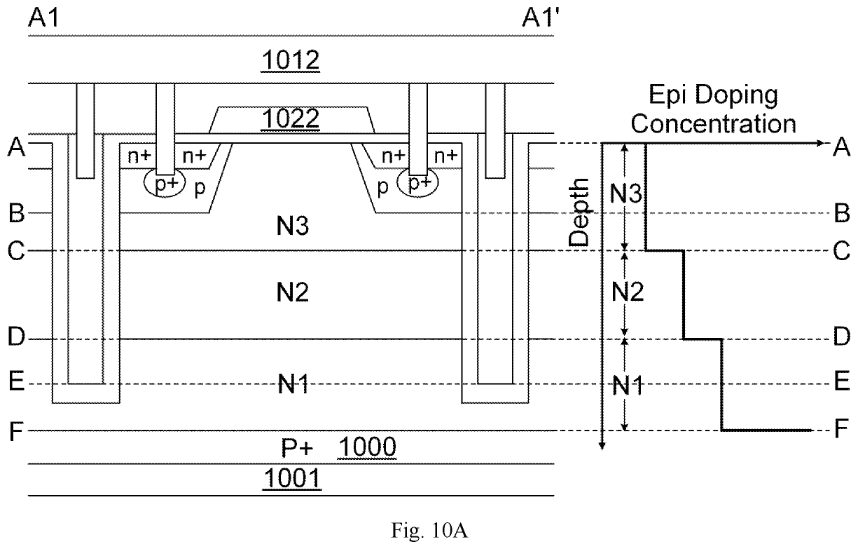

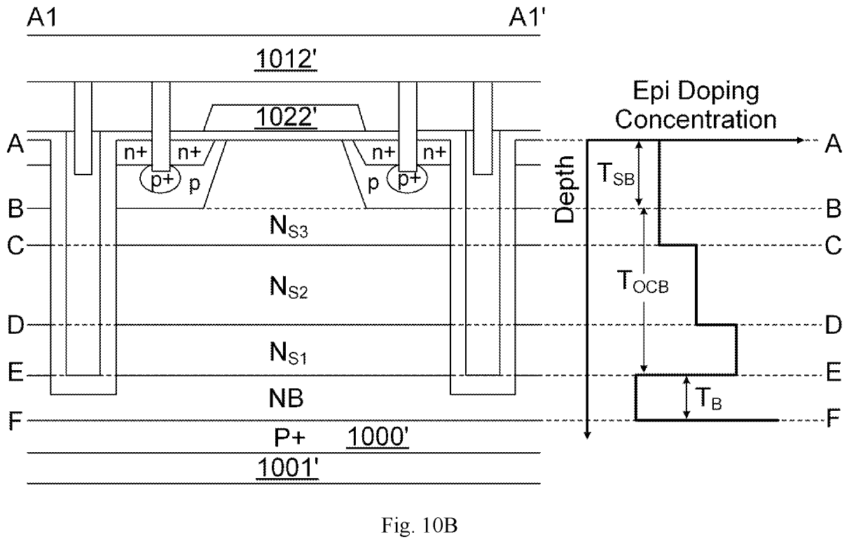

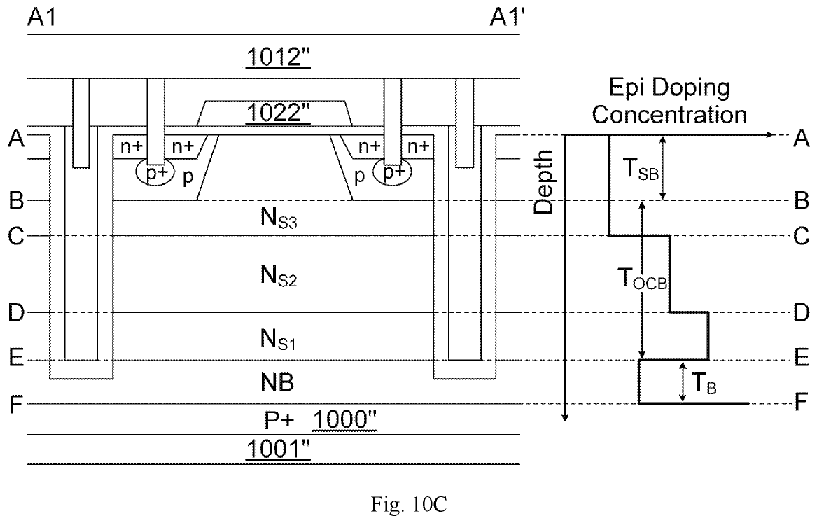

Please refer to FIG. 10A for a cross-sectional view showing another preferred A1-A1′ cross section of FIG. 4A with new and improved device structure having three stepped epitaxial layers wherein the doping concentration variations are depicted along the vertical direction according to the present invention. The N-channel trenched semiconductor power device representing an IGBT device has a similar structure to FIG. 5A, except for the different substrate. In this invention, the IGBT is formed onto a P+ substrate 1000.

Please refer to FIG. 10B for a cross-sectional view showing another preferred A1-A1′ cross section of FIG. 4A with new and improved device structure having multiple stepped epitaxial layers wherein the doping concentration variations are depicted along the vertical direction according to the present invention. The N-channel trenched semiconductor power device representing an IGBT device has a similar structure to FIG. 5B, except for the different substrate. In this invention, the IGBT is formed onto a P+ substrate 1000′.

Please refer to FIG. 10C for a cross-sectional view showing another preferred A1-A1′ cross section of FIG. 4A with new and improved device structure having multiple stepped epitaxial layers wherein the doping concentration variations are depicted along the vertical direction according to the present invention. The N-channel trenched semiconductor power device representing an IGBT device has a similar structure to FIG. 5C, except for the different substrate. In this invention, the IGBT is formed onto a P+ substrate 1000″.

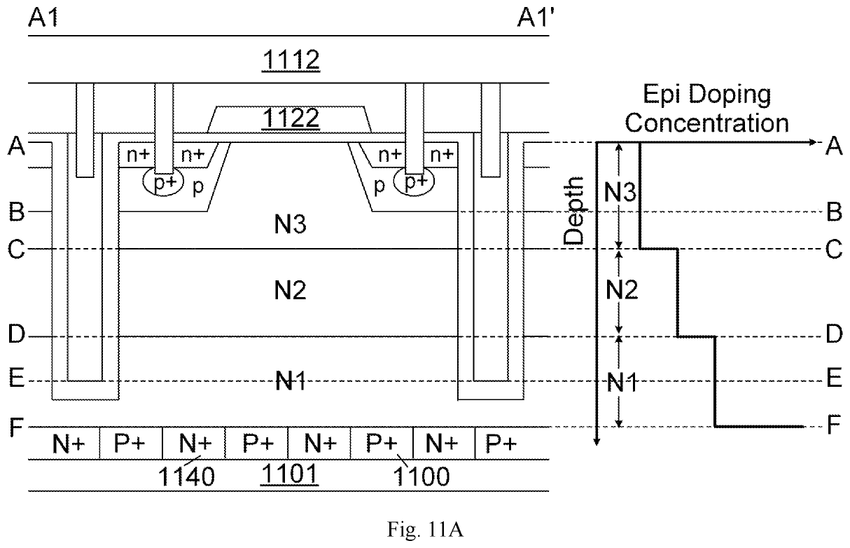

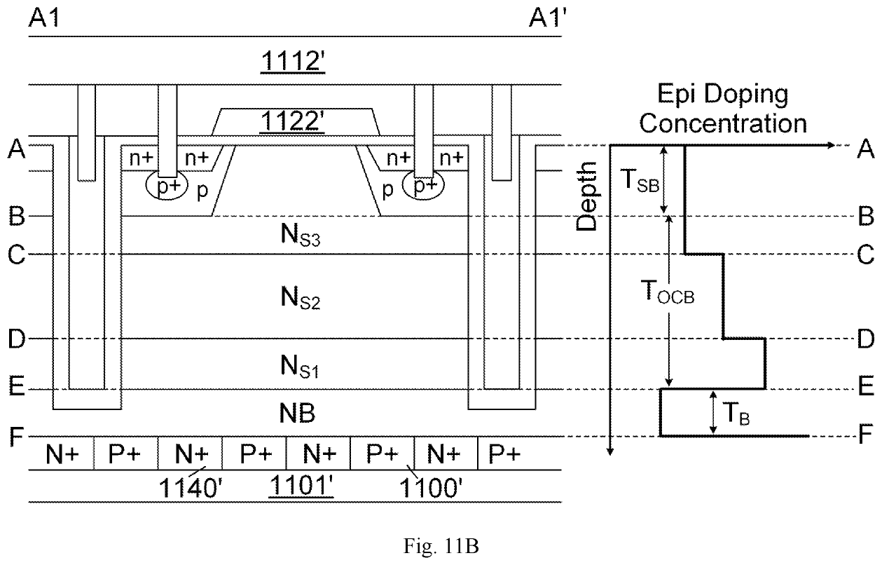

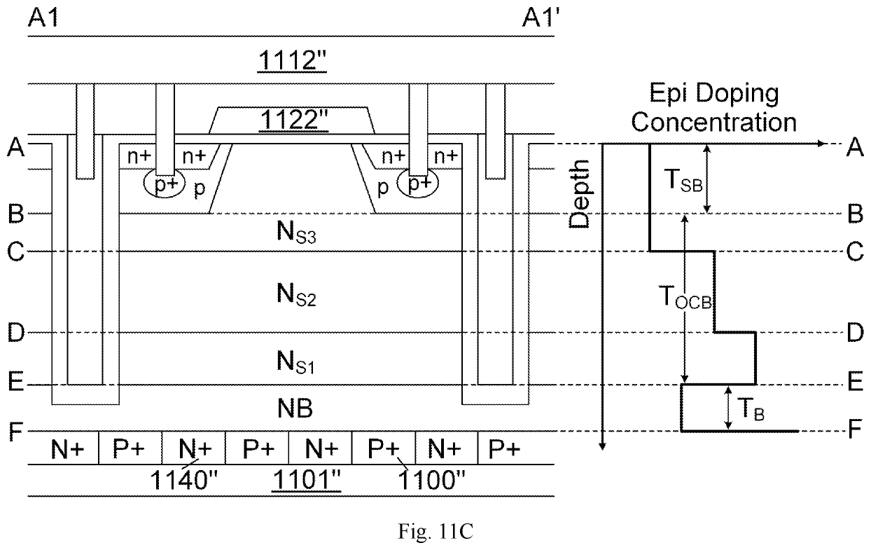

Please refer to FIG. 11A for a cross-sectional view showing another preferred e A1-A1′ cross section of FIG. 4A with new and improved device structure having three stepped epitaxial layers wherein the doping concentration variations are depicted along the vertical direction according to the present invention. The N-channel trenched semiconductor power device representing an IGBT device has a similar structure to FIG. 10A, except that, in FIG. 11A, the IGBT further comprises a plurality of heavily doped N+ regions 1140 formed in the P+ substrate 1100 to form a plurality of alternating P+ and N+ regions in the substrate.

Please refer to FIG. 11B for a cross-sectional view showing another preferred e A1-A1′ cross section of FIG. 4A with new and improved device structure having multiple stepped epitaxial layers wherein the doping concentration variations are depicted along the vertical direction according to the present invention. The N-channel trenched semiconductor power device representing an IGBT device has a similar structure to FIG. 10B, except that, in FIG. 11B, the IGBT further comprises a plurality of heavily doped N+ regions 1140′ formed in the P+ substrate 1100′ to form a plurality of alternating P+ and N+ regions in the substrate.

Please refer to FIG. 11C for a cross-sectional view showing another preferred e A1-A1′ cross section of FIG. 4A with new and improved device structure having multiple stepped epitaxial layers wherein the doping concentration variations are depicted along the vertical direction according to the present invention. The N-channel trenched semiconductor power device representing an IGBT device has a similar structure to FIG. 10C, except that, in FIG. 11C, the IGBT further comprises a plurality of heavily doped N+ regions 1140″ formed in the P+ substrate 1100″ to form a plurality of alternating P+ and N+ regions in the substrate.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A shielded gate trench (SGT) device comprising a plurality of unit cells with each unit cell in an active area comprising:
at least two gate trenches surrounding a deep trench with a pillar shape;
an epitaxial layer of a first conductivity type grown on a substrate;
said deep trench having a deeper trench depth than said at least two gate trenches;
a shielded gate electrode formed within said deep trench and surrounded by a first insulating film;
a source region of said first conductivity type formed near a top surface of said epitaxial layer within said active area;
a body region of a second conductivity type formed underneath said source region;
said shielded gate electrode, said source and body regions shorted together through a source metal; and
an intersection area of said at least two gate trenches adjacent to corners of said deep trench surrounded by said at least two gate trenches, wherein said body region is not formed.

2. The SGT device of claim 1, wherein said gate trench has a square or a rectangular shape top view.

3. The SGT device of claim 1, wherein said gate trench has a rectangular shape top view and is arranged in multiple orientations.

4. The SGT device of claim 1, wherein said epitaxial layer is a single epitaxial layer with an uniform doping concentration.

5. The SGT device of claim 1, wherein said epitaxial layer has multiple stepped epitaxial (MSE) layers with a doping concentration decreasing stepwise in a direction from said substrate toward said body region along sidewalls of said deep trench.

6. The SGT device of claim 1, wherein said epitaxial layer has MSE layers with doping concentrations decreasing stepwise in a direction from a bottom of said shielded gate electrode toward said body region along sidewalls of said deep trench, and a buffer epitaxial layer between a bottom of said shielded gate electrode and said substrate: said epitaxial layer in said buffer region has a doping concentration lower than each of said MSE layers.

7. The SGT device of claim 1, wherein said epitaxial layer has MSE layers with doping concentrations decreasing stepwise in a direction from a bottom of said shielded gate electrode toward said body region along sidewalls of said deep trench, and a buffer epitaxial layer between a bottom of said shielded gate electrode and said substrate; said epitaxial layer in said buffer region has a doping concentration higher than a top layer of said MSE layers but lower than other layers of said MSE layers.

8. The SGT device of claim 1, wherein each of said at least two gate trenches filled with a doped poly-silicon layer padded by a gate oxide layer as a gate electrode;

9. The SGT device of claim 1, wherein each of said of at least two gate trenches are filled with a gate electrode and a second type shielded gate electrode; said second type shielded gate electrode is insulated from said epitaxial layer by a second insulating film, said gate electrode is insulated from said epitaxial layer by a gate oxide, said second type shielded gate electrode and said gate electrode are insulated from each other by an (Inter-Poly Oxide) IPO film, said gate oxide surrounds said gate electrode and has less thickness than said second insulating film.

10. The SGT device of claim 1, wherein said substrate has said first conductivity type.

11. The SGT device of claim 1, wherein said substrate has said second conductivity type.

12. The SGT device of claim 11, further comprising a plurality of heavily doped regions of said first conductivity type in said substrate to form a plurality of alternating P+ and N+ regions in said substrate.

13. A shielded gate trench (SGT) device comprising a plurality of unit cells with each unit cell in an active area, comprising:
a planar gate poly silicon layer as a planar gate electrode having a square or rectangular shape surrounding a deep trench with a pillar shape wherein a shielded gate electrode is formed within said deep trench and surrounded by an insulating film;
a source-body contact disposed between said planar gate electrode and said deep trench;
an epitaxial layer of said first conductivity type grown on a substrate;
a source region of said first conductivity type formed near a top surface of said epitaxial layer within said active area;
a body region of said second conductivity type formed underneath said source region;
said planar gate electrode made of a doped poly-silicon layer padded by a gate oxide layer; and
said shielded gate electrode, said source and body regions shorted together through a source metal.

14. The SGT device of claim 13, wherein said epitaxial layer is a single epitaxial layer with an uniform doping concentration.

15. The SGT device of claim 13, wherein said epitaxial layer has (multiple stepped epitaxial) MSE layers with doping concentrations decreasing stepwise in a direction from said substrate toward said body region along sidewalls of said deep trench.

16. The SGT device of claim 13, wherein said epitaxial layer has MSE layers with doping concentrations decreasing stepwise in a direction from a bottom of said shielded gate electrode toward said body region along sidewalls of said deep trench, and a buffer epitaxial layer between a bottom of said shielded gate electrode and said substrate; said epitaxial layer in said buffer region has a doping concentration lower than each of said MSE layers.

17. The SGT device of claim 13, wherein said epitaxial layer has MSE layers with doping concentrations decreasing stepwise in a direction from a bottom of said shielded gate electrode toward said body region along sidewalls of said deep trench, and a buffer epitaxial layer between a bottom of said shielded gate electrode and said substrate; said epitaxial layer in said buffer region has a doping concentration higher than a top layer of said MSE layers but lower than other layers of said MSE layers.

18. The SGT device of claim 13, wherein said substrate has said first conductivity type.

19. The SGT device of claim 13, wherein said substrate has said second conductivity type.

20. The SGT device of claim 19, further comprising a plurality of heavily doped regions of said first conductivity type in said substrate to form a plurality of alternating P+ and N+ regions in said substrate.
